(19) United States
(12) Patent Application Publication
(10) Pub. No.: US 2008/0181810 A1
(43) Pub. Date: Jul. 31, 2008

(54) Magnetic Film of Oxide-Containing Cobalt Base Alloy, Oxide-Containing Cobalt Base Alloy Target, and Manufacturing Method Thereof

(75) Inventor: Kazuteru Kato, Omuta-shi (JP)

Correspondence Address: THE WEBB LAW FIRM, P.C., 700 KOPPERS BUILDING, 436 SEVENTH AVENUE, PITTSBURGH, PA, 15219, US

(73) Assignee: MITSUI MINING & SMELTING CO., LTD., Tokyo (JP)

(21) Appl. No.: 11/857,061

(22) Filed: Sep. 18, 2007

(30) Foreign Application Priority Data
Sep. 22, 2006 (JP) 2006-257711

(51) Int. Cl. C22C 19/07; C23C 14/00; B22F 7/00

(52) U.S. Cl. 420/439; 420/435; 420/440; 204/192.32; 419/6

(57) ABSTRACT

A magnetic film of an oxide-containing cobalt base alloy has a smaller coercivity difference than conventional magnetic films. A target material and a sputtering target of the invention are capable of forming the magnetic film. A manufacturing method of the target material is also disclosed.

The magnetic film of an oxide-containing cobalt base alloy and the oxide-containing cobalt base alloy target material each have a Fe content of 100 ppm or less. The sputtering target includes the target material bonded to a backing plate. The manufacturing method of the oxide-containing cobalt base alloy target material includes preparing a Co—Cr alloy by melting Cr ingot and at least one Co source selected from Co ingot and Co powder, preparing Co—Cr alloy powder by atomizing the Co—Cr alloy, preparing a mixed powder by mixing the Co—Cr alloy powder, Pt powder and oxide powder, and sintering the mixed powder after forming or simultaneously with forming.

### BACKGROUND OF THE INVENTION

1. Field of the Invention

The present invention relates to a magnetic film of an oxide-containing cobalt base alloy, an oxide-containing cobalt base alloy target, and a manufacturing method thereof. In more detail, it relates to a magnetic film of an oxide-containing cobalt base alloy suitable for application to a magnetic recording film (magnetic recording layer) for a magnetic recording medium, a target material and a sputtering target capable of forming the magnetic film by sputtering technique, and a manufacturing method of the target material.

2. Description of the Related Art

The following properties are required, in general, for the use of a magnetic film as a magnetic recording film (magnetic recording layer) for magnetic recording media like a hard disc medium: a coercivity higher than a certain value, and a minimum difference of in-plane coercivity (difference of magnetic force, hereinafter simply referred to as coercivity difference). Such properties are required because the magnetic recording is impossible without a certain level of coercivity, and reading error occurs frequently if the in-plane coercivity difference of a magnetic film is large. The magnetic recording films should be free of these defects.

Also, the in-plane recording has been a mainstream recording technique for the magnetic recording media, but recently, the vertical recording method has been developed and practically applied in order to increase the magnetic recording density.

Hence, materials of the magnetic films used for the magnetic recording films are changed from Co—Cr—Pt—B which is suitable for the in-plane recording to oxide-containing cobalt base alloys such as Co—Cr—Pt—SiO₂ which are suitable for the vertical recording, as disclosed in Japanese Patent Laid-Open Publication No. 2005-222675, Japanese Patent Laid-Open Publication No. H10-88333 and Japanese Patent Laid-Open Publication No. H7-311929.

A magnetic film of an oxide-containing cobalt base alloy as described above is usually prepared by sputtering a target material having the same composition as that to be obtained in the magnetic film, using a sputtering target in which the target material is bonded to a backing plate made of copper or a copper alloy. The target material is required to have a homogenously dispersed structure of cobalt base alloy phase and oxide phase, and therefore it is generally prepared by powder metallurgy.

However, magnetic films of oxide-containing cobalt base alloys prepared so far have a problem of a large difference of in-plane coercivity, for example 181 to 210 Oe, in the circumferential direction, and fail to meet the above-mentioned performance criteria, although the coercivity itself meets the requirement.

### SUMMARY OF THE INVENTION

An object of the present invention is to provide a magnetic film of an oxide-containing cobalt base alloy having a smaller coercivity difference compared with the currently existing magnetic films, a target material and a sputtering target capable of forming the magnetic film, and a manufacturing method of the target material.

Inventors of the present invention were successful to accomplish the present invention with great efforts on resolving the above-mentioned problem by finding out that the coercivity difference of a magnetic film of an oxide-containing cobalt base alloy can drastically be lowered by decreasing the content of Fe in the magnetic film below a specified level.

That is, the present invention relates to the following items.

A magnetic film of an oxide-containing cobalt base alloy relating to the present invention has a Fe content of 100 ppm or less. The value of ppm unit is based on weight in this description.

The magnetic film of an oxide-containing cobalt base alloy desirably has an in-plane coercivity difference of 110 Oe or less in a circumferential direction.

Furthermore, the magnetic film of an oxide-containing cobalt base alloy preferably contains an oxide of at least one element selected from Si, Ti, and Ta, and further contains at least one metal element selected from Cr and Pt.

An oxide-containing cobalt base alloy target material of the present invention has a Fe content of 100 ppm or less.

Furthermore, the oxide-containing cobalt base alloy target material preferably contains an oxide of at least one element selected from Si, Ti, and Ta, and further contains at least one metal element selected from Cr and Pt.

Further, a sputtering target of the present invention comprises the oxide-containing cobalt base alloy target material and a backing plate, the target material being bonded to the backing plate.

A manufacturing method of an oxide-containing cobalt base alloy target material relating to the present invention comprises the steps of: preparing a Co—Cr alloy by melting Cr ingot and at least one Co source selected from Co ingot and Co powder; preparing Co—Cr alloy powder by atomizing the Co—Cr alloy; preparing a mixed powder by mixing the Co—Cr alloy powder, Pt powder and oxide powder; and sintering the mixed powder after forming or simultaneously with forming.

In the manufacturing method of an oxide-containing cobalt base alloy target material, the oxide is preferably an oxide of at least one element selected from Si, Ti, and Ta.

The magnetic film of an oxide-containing cobalt base alloy of the present invention has a significantly smaller coercivity difference and uniform magnetic properties compared with the conventional magnetic films. Therefore, it can meet the performance criteria required for magnetic recording films (magnetic recording layers) for magnetic recording media. Hence, the magnetic film of an oxide-containing cobalt base alloy of the present invention can be suitably used as a magnetic recording film for magnetic recording media, that is, a magnetic recording medium can include the magnetic film as a magnetic recording film.

With the oxide-containing cobalt base alloy target material and the sputtering target of the present invention, a magnetic film of an oxide-containing cobalt base alloy which is suitable as a magnetic recording film (magnetic recording layer) for magnetic recording media can easily be sputtered on a magnetic recording medium substrate optionally provided with other layers.

Furthermore, according to the manufacturing method of an oxide-containing cobalt base alloy target material of the present invention, it is possible to reduce the Fe content of each raw material powder with ease and no failure. By reducing the Fe content in the raw material powders, the method produces an oxide-containing cobalt base alloy target material that can form a magnetic film having a small coercivity difference. The manufacturing method is particularly suited for producing an oxide-containing cobalt base alloy target material containing Cr.

### DESCRIPTION OF THE PREFERRED EMBODIMENTS

The present invention is explained in detail below.

Regarding the magnetic film of an oxide-containing cobalt base alloy and the oxide-containing cobalt base alloy target material of the present invention, the oxide-containing cobalt base alloy is a material which contains Co as a major component and in which a cobalt base alloy phase and an oxide (ceramic) phase are homogenously dispersed.

The oxide-containing cobalt base alloy preferably contains, in addition to Co, an oxide of at least one element selected from Si, Ti, and Ta, and further contains at least one metal element selected from Cr and Pt.

Typical examples of the oxide-containing cobalt base alloys include Co—Cr—Pt-Oxide, Co—Cr-Oxide, Co—Pt-Oxide, and the like. Among them, Co—Cr—Pt-Oxide is preferable in terms of a large coercivity. Concerning the composition of Co—Cr—Pt-Oxide, the content of Co—Cr—Pt is desired to be in the range from 70 to 99 mol %, and the rest is the oxide content (mol %), wherein the Cr content in Co—Cr—Pt is more than zero and not more than 20 at %, the Pt content in Co—Cr—Pt is more than zero and not more than 30 at %, and the rest is the Co content (at %).

More concretely, examples of the above-described Co—Cr—Pt-Oxide include Co—Cr—Pt—SiO₂ (hereinafter, referred also to as CCPS), Co—Cr—Pt—TiO₂ (hereinafter, referred also to as CCP—TiO₂), Co—Cr—Pt—Ta₂O₅ (hereinafter, referred also to as CCP—Ta₂O₅), and the like.

A magnetic film of the oxide-containing cobalt base alloy obtained by sputtering the oxide-containing cobalt base alloy target material has a large coercivity and is expected to be useful as a magnetic recording film for the vertical recording type magnetic recording media.

As mentioned above, the oxide-containing cobalt base alloy target material is usually manufactured by powder metallurgy of mixed powder obtained by mixing raw material powders of constituting components. This is because it is extremely difficult that a target material obtained by the conventional melting and casting has a structure in which the cobalt base alloy phase and the oxide phase are homogenously dispersed.

In the powder metallurgy process, in general, the mixed powder (or slurry containing the mixed powder) obtained by mixing the raw material powders of constituting components is fired to sinter the particles of the powder. This sintering is performed after the mixed powder is formed into a compact or simultaneously with the forming.

However, impurities contained in the raw material powders which cannot be removed by sintering and the like remain in the resulting target material in the powder metallurgy process. In addition, such impurities contained in the target material also remain in the magnetic film formed by sputtering a sputtering target having the target material.

Therefore, the inventors of the present invention have studied a relationship between the coercivity difference and impurities contained in the magnetic film. They have found that the coercivity difference is affected substantially by Fe among the impurities, and the coercivity difference can drastically be reduced by decreasing the Fe content below a certain level. When the Fe content in the magnetic film exceeds such a level, it is inferred that Fe tends to be locally segregated and cause a coercivity distribution within the film, especially, in the in-plane circumferential direction of the film.

Concretely, when the Fe content in the magnetic film of an oxide-containing cobalt base alloy is reduced to 100 ppm or less, preferably 80 ppm or less, and more preferably 60 ppm or less, the in-plane coercivity difference in the circumferential direction of the magnetic film can be decreased to 110 Oe or less, preferably 100 Oe or less.

The lower the Fe content of the magnetic film, the better is it from the viewpoint of reducing the coercivity difference. There is no lower limit of the Fe content, but usually the Fe content of 0.05 ppm or more is permissible since such a level of the Fe content actually does not affect the coercivity difference of the magnetic film.

For example, such a magnetic film of an oxide-containing cobalt base alloy in which the Fe content is reduced to not more than a certain level can be prepared by an ordinary sputtering method using a sputtering target provided with the oxide-containing cobalt base alloy target material that has a Fe content reduced to not more than the desired level.

The target material may be an oxide-containing cobalt base alloy target material containing Fe in an amount of 100 ppm or less, preferably 80 ppm or less, and more preferably 60 ppm or less.

The lower the Fe content of the target material, the better is it from the viewpoint of reducing the coercivity difference of the magnetic film obtained by sputtering. The lower limit of the Fe content is not specified, but the Fe content approximately of the same level as the lower limit of the magnetic film is permissible.

As mentioned above, the Fe content in the target material manufactured by powder metallurgy is affected by the content of Fe contained as an impurity in the raw material powders. Therefore, it is preferable to use raw material powders having a reduced Fe content in the manufacturing of the target material.

The raw material powders of constituting components are preferably such that when they are mixed based on a composition ratio of the objective oxide-containing cobalt base alloy target material, the Fe content in the mixed powder meets the above condition, specifically not more than 100 ppm, preferably not more than 80 ppm, more preferably not more than 60 ppm.

Therefore, the Fe content in each of the raw material powders of constituting components is desirably 100 ppm or less, preferably 80 ppm or less, and more preferably 60 ppm or less.

The raw material powders of constituting components may be commercially available as long as they satisfy the Fe content. Such powders may be produced into the target material of the invention by powder metallurgy. Specifically, the raw material powders are weighed according to a desired composition of the target material and are mixed by an ordinary method; and the mixed powder is sintered after forming or simultaneously with forming.

However, such commercially available powders often do not meet the required Fe content for use in the present invention. Specifically, the Fe content in commercially available powders is increased during the production of the powder: for example, a raw material originally contains much Fe, and a raw material ingot is pulverized into powder with an iron-made pulverizer.

Especially, a commercially available Cr powder contains a high level of Fe, usually several hundred ppm (for example, 780 ppm). Therefore, it is extremely difficult that when a commercially available Cr powder is used, the obtainable oxide-containing cobalt base alloy target material containing Cr satisfies the above Fe content.

On the other hand, a commercially available Cr ingot contains a lower level of Fe compared with the commercially available Cr powder, for example, below a decimal like 0.14 ppm. However, if such Cr ingot is pulverized into powder by a pulverizing machine, the resulting Cr powder will be contaminated with Fe during the pulverizing so that the Fe content of the Cr powder will surpass that of the commercially available Cr powder. Hence, use of a commercially available Cr ingot cannot solve the problem.

Atomization is an alternative technique for obtaining powder from an ingot without the Fe contamination. However, because Cr is a refractory metal having a high melting point of 1903° C., it is difficult to stably supply the molten metal to an atomization apparatus. Therefore, it is practically impossible to obtain Cr powder directly from a Cr ingot by the atomization method.

The inventors of the present invention have found in the above-mentioned circumstance that when a Cr ingot and at least one Co raw material selected from Co ingot and Co powder are molten together to produce a Co—Cr alloy and the obtained Co—Cr alloy is atomized, Co—Cr powder is produced easily. By forming the Co—Cr alloy, the liquidus temperature is lowered compared with that of Cr alone, and therefore a melt of the Co—Cr alloy can stably be supplied to the atomization apparatus.

Concerning the atomization method, the gas atomization method is preferred in which the atomization conditions are not specifically limited and are appropriately determined based on known conditions.

Also, concerning the Co source, the Fe content is lower in a commercially available Co ingot than in a commercially available Co powder. Accordingly, the Fe content of the target material may be further reduced by using a Co ingot and Co powder in combination or a Co ingot alone, more effectively than by using a commercially available Co powder alone. Further, the use of Co ingot alone is preferable because the effect of reduction of the Fe content becomes more prominent.

It is needless to say that the Cr ingot, Co ingot and Co powder each preferably have a Fe content of 100 ppm or less, more preferably 80 ppm or less, and further preferably 60 ppm or less. That is, some of commercially available Cr ingots, Co ingots, and Co powders have a high level of the Fe content, and not all commercially available ones can be used as raw materials.

The Co—Cr powder produced as described above may be mixed with oxide powder and optionally other metal powder (for example, Pt powder) each having a Fe content of 100 ppm or less, preferably 80 ppm or less, and more preferably 60 ppm or less. The resultant mixed powder may be processed by powder metallurgy in which the mixed powder is sintered after forming or simultaneously with forming. Thus, an oxide-containing cobalt base alloy target material containing Cr and having a Fe content of 100 ppm or less may be produced.

There are several methods for mixing the powders; for example, ball mill mixing, V-blender mixing, bag mixing, mixing by screw mixer, and other known methods. There are also several forming methods; for example, cold isostatic pressing, metal mold casting, and other known methods using a mold. There are also several methods for sintering simultaneously with forming; for example, hot pressing (HP), hot isostatic pressing (HIP), and the like. The conditions in these methods are not specifically limited and may be chosen appropriately from any known conditions.

The sputtering target of the present invention is formed by bonding the above-described oxide-containing cobalt base alloy target material to a backing plate through a bonding material. The bonding material may be In metal or an In alloy.

A magnetic film of an oxide-containing cobalt base alloy may be sputtered by a common method using the above sputtering target, on a nonmagnetic substrate or a laminate of a nonmagnetic substrate, a nonmagnetic underlayer, and a soft magnetic underlayer laminated in this order. Consequently, a magnetic recording medium is manufactured which has the magnetic film as a magnetic recording film (magnetic recording layer). Examples of the nonmagnetic substrates include glass substrates, Al-alloy substrates, resin substrates and the like. Examples of materials of the nonmagnetic underlayers include Ru, Ru-alloys, Ti and the like. Examples of materials of the soft magnetic underlayers include Co—Nb—Zr alloy, Co—Zr—Ta alloy, Ni—Fe alloy, Co—Fe—B alloy and the like.

Further, a protection layer may be optionally provided on the magnetic recording layer of the magnetic recording medium. Examples of materials of the protection layers include carbon and the like.

### EXAMPLES

The present invention is explained in more detail by showing the following examples but not limited to them.

The method for measuring the Fe content used in the examples is as follows:

### <Measurement of the Fe Content>

An ICP emission spectrometer, SPS3000 (manufactured by Seiko Instruments Inc.), was used for measuring the Fe content of each sample of ingot, powder, target material, and magnetic film (magnetic recording layer).

### Example 1

### <Preparation of CCPS Target Material and Sputtering Target>

An atomized Co—Cr powder was prepared by atomization processing according to the following procedures (1) to (5), using commercially available Co ingot and Cr ingot each having a purity of 99.9% and containing Fe in an amount of 10 ppm and 0.14 ppm, respectively.

Atomization Procedure (Apparatus: manufactured by Nisshin Giken Co., Ltd.)
(1) Drawing a vacuum to 3×10⁻⁵ Torr,
(2) Filling Ar to a pressure of −10 cmHg,
(3) Preparing a Co—Cr alloy melt by melting the raw materials (1.5 kg in total) at 1680° C.,
(4) Atomizing the alloy using Ar as an atomization gas at an atomization temperature of 1600° C. and an atomization gas pressure of 30 kgf/cm², and
(5) Classifying the particles in a glove box using a sieve having a mesh of 250 μm.

The Fe content of the atomized Co—Cr powder was 5 ppm.

A mixed powder was then prepared by weighing the atomized powder and commercially available Pt powder and SiO₂ powder each having a purity of 99.9% (the Fe contents were 4 ppm and 8 ppm, respectively) at a prescribed composition (91 mol % of Co—Cr—Pt (Cr: 10 at %, Pt: 16 at %, Co: the rest (at %)) and 9 mol % of SiO₂) , and then mixing these powders in a ball mill using zirconia balls.

The resultant mixed powder was hot pressed under the following HP conditions to give a compact:
(1) HP temperature: 1300° C.,
(2) Pressure: 200 kg/cm²,
(3) Hold time: 120 main, and
(4) Size of the compact: 4.3 inch in diameter, 7 mm in thickness.

A CCPS target material was prepared by lathe machining the compact. The Fe content of this CCPS target material was 27 ppm.

A CCPS sputtering target (hereinafter, simply referred also to as CCPS target) was prepared by bonding the CCPS target material to a copper backing plate through an In bonding material.

### <Preparation of CCPS Magnetic Film (Magnetic Recording Layer)>

A nonmagnetic underlayer (Ru layer) was formed in 200 A thickness on a substrate made of reinforced glass of 2.5 inch diameter by sputtering a Ru target using a sputtering apparatus (a multi-chamber sputtering apparatus with a static load-lock system MSL-464, manufactured by Tokki Corporation) under the conditions of no substrate heating at 20 mTorr of Ar gas pressure.

Subsequently, a soft magnetic underlayer (Co—Nb—Zr layer) was formed in 2000 Å thickness on the above-described nonmagnetic underlayer by sputtering a Co—Nb—Zr target under the conditions of no substrate heating at 5 mTorr of Ar gas pressure. The target used herein contained 87 at % of Co, 6 at % of Nb and 7 at % of Zr.

Further, a magnetic recording layer (CCPS magnetic film) was formed in 200 Å thickness on the above-described soft magnetic underlayer by sputtering the above-described CCPS target under the conditions of no substrate heating at 5 mTorr of Ar gas pressure.

Then, a protection layer (carbon layer) was formed in 50 Å thickness on the above-described magnetic recording layer by sputtering a carbon target under the conditions of no substrate heating at 5 mTorr of Ar gas pressure. Thus, a vertical recording type magnetic recording medium was prepared.

The in-plane coercivity of the magnetic recording layer was measured with a vibrating sample magnetometer, Model VSM, manufactured by TOEI Industry, Co., Ltd., in the circumferential direction at a radius of 28.5 mm at equally distributed 8 points. The coercivity difference was determined to be 99 Oe as a difference between a maximum value and a minimum value among the 8 points. Thus, the CCPS magnetic film showed a very excellent performance as a magnetic recording film.

Separately, a single layer of a CCPS magnetic film was formed in 1 μm thickness on another substrate by sputtering the above-described CCPS target. The Fe content of the CCPS magnetic film was determined to be 26 ppm.

These results are summarized in Table 1.

### Comparative Example 1

A mixed powder was prepared by weighing commercially available Co powder, Cr powder, Pt powder and SiO₂ powder, each having a purity of 99.9% and a Fe content of 55 ppm, 780 ppm, 4 ppm, and 8 ppm, respectively, at a prescribed composition (the same as mentioned in Example 1), and mixing these powders in a ball mill using zirconia balls. Except that the mixed powder was used, other procedures were the same as described in Example 1.

The resulting CCPS target material contained Fe in an amount of 114 ppm, and the resulting CCPS magnetic film contained Fe in an amount of 117 ppm and had a coercivity difference of 210 Oe. The magnetic film was not satisfactory as a magnetic recording film.

These results are summarized in Table 1.

### Comparative Example 2

Commercially available Cr ingot (purity: 99.9%, Fe content: 0.14 ppm) was melt spun into a foil ribbon and was quenched. The foil ribbon was then mechanically pulverized into powder (Fe content: 3500 ppm). The resultant Cr powder was mixed with commercially available Co powder, Pt powder and SiO₂ powder each having a purity of 99.9% and having a Fe content of 55 ppm, 4 ppm, and 8 ppm, respectively, at a prescribed composition (the same as described in Example 1) in a ball mill using zirconia balls. Except that the mixed powder was used, other procedures were the same as described in Example 1.

The resulting CCPS target material contained Fe in an amount of 420 ppm, and the resulting CCPS magnetic film contained Fe in an amount of 410 ppm and had a coercivity difference of 212 Oe. The magnetic film was not satisfactory as a magnetic recording film.

These results are summarized in Table 1.

### Comparative Example 3

Except that a commercially available Cr ingot having a purity of 99.9% (Fe content: 0.14 ppm) alone was atomized at a melting temperature of 1950° C., other procedures were the same as described in Example 1.

As a result, it was not possible to atomize the Cr ingot because the molten Cr solidified at the tip of the nozzle outlet of the atomization apparatus used.

TABLE 1

| | | Fe content | | |
|---|---|---|---|---|
| | Cr raw | (ppm) | Fe content | Coercivity |
| | material/ | of target | (ppm) of CCPS | difference |
| | treatment | material | magnetic film | (Oe) |
| Example 1 | Cr ingot/ | 27 | 26 | 99 |
| | Atomization | | | |
| | after Co—Cr | | | |
| | alloy | | | |
| | preparation | | | |
| Comparative | Commercially | 114 | 117 | 210 |
| Example 1 | available Cr | | | |
| | powder/No | | | |
| | treatment | | | |
| Comparative | Cr ingot/ | 420 | 410 | 212 |
| Example 2 | Mechanical | | | |
| | pulverization | | | |

### Example 2

### <Preparation of CCP—TiO₂ Target Material and Sputtering Target>

A mixed powder was prepared by weighing the atomized powder obtained in Example 1, and commercially available Pt powder and TiO₂ powder each having a purity of 99.9% and containing Fe in an amount of 4 ppm and 20 ppm, respectively at a prescribed composition (91 mol % of Co—Cr—Pt (Cr: 10 at %, Pt: 16 at %, Co: the rest (at %)), and 9 mol % of TiO₂), and mixing these powders in a ball mill using zirconia balls.

The resultant mixed powder was hot pressed under the same conditions as described in Example 1 to give a compact. The compact was processed by lathe machining to produce a CCP—TiO₂ target material. The CCP—TiO₂ target material contained Fe in an amount of 65 ppm.

A CCP—TiO₂ sputtering target was prepared by bonding the CCP—TiO₂ target material to a copper backing plate through an In bonding material.

### <Preparation of CCP—TiO₂ Magnetic Film (Magnetic Recording Layer)>

A nonmagnetic underlayer, a soft magnetic underlayer and a magnetic recording layer (CCP—TiO₂ magnetic film) were successively formed on a substrate under the same conditions as described in Example 1 to form a multilayer, except that the above-mentioned CCP—TiO₂ sputtering target was used.

Then, according to the same procedure as described in Example 1, a protection layer was formed on the magnetic recording layer. Thus, a magnetic recording medium was prepared. Coercivities of the magnetic recording layer were measured and the coercivity difference was determined to be 92 Oe. The CCP—TiO₂ magnetic film was found to show very excellent performance as a magnetic recording layer.

Separately, a CCP—TiO₂ magnetic film was prepared on a substrate in the same manner as in Example 1. The Fe content of the film was determined to be 55 ppm.

These results are summarized in Table 2.

### Comparative Example 4

A mixed powder was prepared by weighing commercially available powders of Co, Cr, Pt and TiO₂, each having a purity of 99.9% and containing Fe in an amount of 55 ppm, 780 ppm, 4 ppm, and 20 ppm, respectively, at a prescribed composition (the same as described in Example 2), and mixing these powders in a ball mill using zirconia balls. Except that the mixed powder was used, other procedures were the same as described in Example 2.

The resulting CCP—TiO₂ target material contained Fe in an amount of 168 ppm, and the resulting CCP—TiO₂ magnetic film contained Fe in an amount of 154 ppm and had a coercivity difference of 227 Oe. The magnetic film was not satisfactory as a magnetic recording film.

These results are summarized in Table 2.

TABLE 2

| | | Fe content | Fe content | |
|---|---|---|---|---|
| | Cr raw | (ppm) | (ppm) of | Coercivity |
| | material/ | of target | CCP-TiO₂ | difference |
| | treatment | material | magnetic film | (Oe) |
| Example 2 | Cr ingot/ | 65 | 55 | 92 |
| | Atomization | | | |
| | after Co—Cr | | | |
| | alloy | | | |
| | preparation | | | |
| Comparative | Commercially | 168 | 154 | 227 |
| Example 4 | available Cr | | | |
| | powder/No | | | |
| | treatment | | | |

### Example 3

### <Preparation of CCP—Ta₂O₅ Target Material and Sputtering Target>

A mixed powder was prepared by weighing the atomized powder obtained in Example 1 and commercially available powders of Pt and Ta₂O₅ each having a purity of 99.9% and containing Fe in an amount of 4 ppm and 23 ppm, respectively, at a prescribed composition (91 mol % of Co—Cr—Pt (Cr: 10 at %, Pt: 16 at %, Co: the rest (at %)), and 9 mol % of Ta₂O₅) , and mixing these powders in a ball mill using zirconia balls.

The resulting mixed powder was hot pressed under the same conditions as described in Example 1 to give a compact. The compact was processed by lathe machining to produce a CCP—Ta₂O₅ target material. The CCP—Ta₂O₅ target material contained Fe in an amount of 78 ppm.

The CCP—Ta₂O₅ target material was bonded to a copper backing plate through an In bonding material to form a CCP—Ta₂O₅ sputtering target.

### <Preparation of CCP—Ta₂O₅ Magnetic Film (Magnetic Recording Layer)>

A nonmagnetic underlayer, a soft magnetic underlayer and a magnetic recording layer (CCP—Ta₂O₅ magnetic film) were formed successively on a substrate under the same conditions as described in Example 1 to form a multilayer, except that the above-mentioned CCP—Ta₂O₅ sputtering target was used.

Then, according to the same procedure as described in Example 1, a protection layer was formed on the above-described magnetic recording layer. Thus, a magnetic recording medium was prepared. Coercivities of the magnetic recording layer were measured and the coercivity difference was determined to be 80 Oe. It was thus found that the CCP—Ta₂O₅ magnetic film was very excellent as a magnetic recording film.

Separately, a CCP—Ta₂O₅ magnetic film was prepared on a substrate in the same manner as in Example 1. The Fe content was determined to be 56 ppm.

These results are summarized in Table 3.

### Example 4

### <Preparation of CCP—Ta₂O₅ Target Material and Sputtering Target>

A Co—Cr atomized powder was prepared according to the same method as described in Example 1, except that the Cr ingot was a commercially available Cr ingot having a purity of 99.9% (Fe content 34 ppm). A CCP—Ta₂O₅ target material was prepared according to the same method as described in Example 3, except that the Co—Cr atomized powder was used. The Fe content of the CCP—Ta₂O₅ target material was 96 ppm.

The CCP—Ta₂O₅ target material was bonded to a copper backing plate through an In bonding material to produce a CCP—Ta₂O₅ sputtering target.

### <Preparation of CCP—Ta₂O₅ Magnetic Film (Magnetic Recording Layer)>

A nonmagnetic underlayer, a soft magnetic underlayer and a magnetic recording layer (CCP—Ta₂O₅ magnetic film) were successively formed on a substrate according to the same method as described in Example 1 to form a multilayer, except that the above-mentioned CCP—Ta₂O₅ sputtering target was used.

Then, according to the same procedure as described in Example 1, a protection layer was formed on the above-described magnetic recording layer. Thus, a magnetic recording medium was prepared. Coercivities of the magnetic recording layer were measured and the coercivity difference was determined to be 102 Oe. It was thus found that the CCP—Ta₂O₅ magnetic film was very excellent as a magnetic recording film.

Separately, a CCP—Ta₂O₅ magnetic film was prepared on a substrate in the same manner as in Example 1. The Fe content was determined to be 70 ppm.

These results are summarized in Table 3.

### Comparative Example 5

A mixed powder was prepared by weighing commercially available powders of Co, Cr, Pt and Ta₂O₅ each having a purity of 99.9% and containing Fe in an amount of 55 ppm, 780 ppm, 4 ppm, and 23 ppm, respectively, at a prescribed composition (the same as described in Example 3), and mixing these powders in a ball mill using zirconia balls. Except that the mixed powder was used, other procedures were the same as described in Example 3.

The Fe content of the resulting CCP—Ta₂O₅ target material was 196 ppm, and the Fe content of the resulting CCP—Ta₂O₅ magnetic film was 175 ppm. The coercivity difference was 220 Oe. The magnetic film was not satisfactory as a magnetic recording film.

These results are summarized in Table 3.

TABLE 3

| | | Fe content | Fe content | |
|---|---|---|---|---|
| | Cr raw | (ppm) | (ppm) of | Coercivity |
| | material/ | of target | CCP-Ta₂O₅ | difference |
| | treatment | material | magnetic film | (Oe) |
| Example 3 | Cr ingot/ | 78 | 56 | 80 |
| | Atomization | | | |
| | after Co—Cr | | | |
| | alloy | | | |
| | preparation | | | |
| Example 4 | Cr ingot/ | 96 | 70 | 102 |
| | Atomization | | | |
| | after Co—Cr | | | |
| | alloy | | | |
| | preparation | | | |
| Comparative | Commercially | 196 | 175 | 220 |
| Example 5 | available Cr | | | |
| | powder/No | | | |
| | treatment | | | |

1. A magnetic film of an oxide-containing cobalt base alloy having a Fe content of 100 ppm or less.

2. The magnetic film of an oxide-containing cobalt base alloy according to claim 1, wherein the magnetic film has an in-plane coercivity difference of 110 Oe or less in a circumferential direction.

3. The magnetic film of an oxide-containing cobalt base alloy according to claim 1, wherein the magnetic film contains an oxide of at least one element selected from Si, Ti, and Ta, and further contains at least one metal element selected from Cr and Pt.

4. An oxide-containing cobalt base alloy target material having a Fe content of 100 ppm or less.

5. The oxide-containing cobalt base alloy target material according to claim 4, wherein the target material contains an oxide of at least one element selected from Si, Ti, and Ta, and further contains at least one metal element selected from Cr and Pt.

6. A sputtering target comprising the oxide-containing cobalt base alloy target material of claim 4 and a backing plate, the target material being bonded to the backing plate.

7. A manufacturing method of an oxide-containing cobalt base alloy target material, comprising the steps of: preparing a Co—Cr alloy by melting Cr ingot and at least one Co source selected from Co ingot and Co powder; preparing Co—Cr alloy powder by atomizing the Co—Cr alloy; preparing a mixed powder by mixing the Co—Cr alloy powder, Pt powder and oxide powder; and sintering the mixed powder after forming or simultaneously with forming.

8. The manufacturing method according to claim 7, wherein the oxide is an oxide of at least one element selected from Si, Ti, and Ta.

9. The magnetic film of an oxide-containing cobalt base alloy according to claim 2, wherein the magnetic film contains an oxide of at least one element selected from Si, Ti, and Ta, and further contains at least one metal element selected from Cr and Pt.

10. A sputtering target comprising the oxide-containing cobalt base alloy target material of claim 5 and a backing plate, the target material being bonded to the backing plate.
